(19) United States
(12) Patent Application Publication
(10) Pub. No.: US 2015/0355693 A1
(43) Pub. Date: Dec. 10, 2015

(54) Jacket for a Handheld Electronic Device and Handheld Assembly Having the Jacket and the Handheld Electronic Device

(71) Applicant: Sunonwealth Electric Machine Industry Co., Ltd., Kaohsiung (TW)

(72) Inventors: Feng-Ming Chang, Kaohsiung (TW); Shih-Hang Lin, Kaohsiung (TW); Chia-Chin Wu, Kaohsiung (TW)

(21) Appl. No.: 14/689,108

(22) Filed: Apr. 17, 2015

(30) Foreign Application Priority Data
Jun. 4, 2014 (TW) 103119413

(51) Int. Cl. G06F 1/20; H05K 5/02; H05K 7/20; H05K 5/00

(52) U.S. Cl. CPC G06F 1/206; G06F 1/203; H05K 5/0086; H05K 5/0213; H05K 5/0247; H05K 5/0004; H05K 7/20209

(57) ABSTRACT

A jacket for a handheld electronic device includes: a housing adapted to couple with a handheld electronic device; a fan mounted in the housing; and a control unit electrically connecting with the fan and adapted to electrically connect with the handheld electronic device, with the control unit capable of controlling the fan according to a control command outputted by the handheld electronic device.

### BACKGROUND OF THE INVENTION

1. Field of the Invention

The present invention generally relates to a jacket for a handheld electronic device and, more particularly, to a jacket capable of cooling a handheld electronic device combined therewith by a fan.

2. Description of the Related Art

With the improvement of semiconductor technology, new kinds of handheld electronic devices, such as handheld computers, handheld game consoles, mobile phones, e-book readers, smart phones, tablets or phablets, are put into the consumer market rapidly and frequently. By the digital content installed inside, these handheld electronic devices can provide various functions such as communication, document processing and entertainment. The prices of handheld electronic devices also largely increase with the increasing of functions provided by the handheld electronic devices. Accordingly, there comes out a need of physical protection to handheld. electronic devices, that is, a jacket for combining to and protecting the surface of the handheld electronic devices.

This jacket may not only prevent the protected handheld electronic device from inadvertent operation or scratches, but also improve or change the look of the handheld electronic device.

However, conventional jackets in the present consumer market are usually unable to cool the combined handheld electronic devices, and the heat caused by the long operating time or increased computing load may be accumulated in the handheld electronic devices. Apparently, the heat inside the handheld electronic devices can further result in operational fault, low efficiency, short lifetime or permanent damage to the handheld electronic devices. Therefore, an improved jacket for a handheld electronic device is in need.

### SUMMARY OF THE INVENTION

What is needed is a jacket for a handheld electronic device, which is able to cool the handheld electronic device in accordance with a control command or control signal outputted by the handheld electronic device.

Another need is a jacket for a handheld electronic device, which is able to cool the handheld electronic device in accordance with the temperature of the handheld electronic device.

In one implementation, a jacket for a handheld electronic device includes: a housing adapted to couple with a handheld electronic device; a fan mounted in the housing; and a control unit electrically connecting with the fan and adapted to electrically connecting with the handheld electronic device, with the control unit capable of controlling the fan according to a control command outputted by the handheld electronic device.

In this implementation, one or more of the following features may be included that: the control unit is arranged inside the housing; the control unit is arranged inside the fan; according to the control command, the control unit generates a driving signal to actuate the fan; according to the control command, the control unit generates a control signal for a fan driver to actuate the fan; the control signal is a PWM (Pulse Width Modulation) signal, a PAM (Pulse Amplitude Modulation) signal, or a PFM (Pulse Frequency Modulation) signal; the control unit is a microcontroller; the control unit is an application-specific integrated circuit able to serve as a fan controller and driver; the control unit is a circuit board having a fan controller and a fan driver; the housing has at least one sensor electrically connecting with the control unit; the at least one sensor comprises at least one of a distance sensor, a deformation sensor, an electromagnetism sensor, and a temperature sensor; the distance sensor is an optical sensor or a limit switch; the deformation sensor is a piezoelectric sensor or a strain gage; the electromagnetism sensor is a proximity switch or a touch element; the temperature sensor is a thermistor or a surface-attached thermometer; the housing has a battery connecting with the control unit and fan electrically; the battery supplies electrical power to the control unit and the fan; the housing has an air purifier electrically connecting to the control unit; the air purifier is an air negative ion generator or an electronic air freshener; the housing has an electrical connector electrically connecting with the control unit and adapted to connect with the handheld electronic device electrically; the handheld electronic device provides electrical power to the control unit and the fan; the control command is generated by an application program executed by the handheld electronic device; the control command is generated by a basic input/output system of the handheld electronic device; wherein the control unit determines whether the handheld electronic device is in a high power-consumption state according to the control command, wherein the control unit actuates the fan to turn if the handheld electronic device is in the high power-consumption state, or keeps detecting whether the handheld electronic device enters the high power-consumption state according to the control command if the handheld electronic device is not in the high power-consumption state; the high power-consumption state is a communication state, an online state, or a high computing load state; when the control unit actuates the fan, the control unit speeds up rotation of the fan if a surface of the handheld electronic device is heated over a predetermined temperature, or the control unit maintains a rotational speed of the fan if the surface of the handheld electronic device is not heated over the predetermined temperature; the control unit gradually increases a rotational speed of the fan to a target speed after the fan is actuated; the housing has an outer member and an inner member coupling with the outer member; the outer member has an inlet portion and an outlet portion, an air channel is formed between the inlet and outlet portions, and the fan is positioned in the air channel; the inner member has an air-guiding portion facing the outer member and disposed between the inlet and outlet portions; the outer member has a first coupling portion, the inner member has a second coupling portion, and the first and second coupling portions jointly couple with the handheld electronic device; and the first coupling portion comprises a positioning wall; the second coupling portion comprises an engaging groove.

In another implementation, a handheld assembly includes: a jacket including a housing; a handheld electronic device coupling with the housing and generating a control signal; and a fan mounted in the housing, electrically connecting with the handheld electronic device, and operating accordingly to the control signal.

In this implementation, one or more of the following features may be included that: the handheld electronic device has a control unit generates the control signal; the control signal is adapted to be supplied to a fan driver to actuate the fan; the control signal is a PWM signal, a PAM signal, or a PFM signal; the housing has an electrical connector electrically connecting with the fan and the handheld electronic device; the handheld electronic device provides electrical power to the fan; the housing has a battery connecting with the fan electrically; the battery supplies electrical power to the fan; the housing has an air purifier adjacent to the fan; the air purifier is an air negative ion generator or an electrical air freshener; the control signal is generated by an application program executed by the handheld electronic device; the control signal is generated by a basic input/output system of the handheld electronic device; according to a control command, the control unit determines whether the handheld electronic device is in a high power-consumption state, wherein the control unit actuates the fan to turn if the handheld electronic device is in the high power-consumption state, or keeps detecting whether the handheld electronic device enters the high power-consumption state according to the control command if the handheld electronic device is not in the high power-consumption state; the high power-consumption state is a communication state, an online state, or a high computing load state; the control unit gradually increases a rotational speed of the fan to a target speed after the fan is actuated; the housing has an outer member and an inner member coupling with the outer member; the outer member has an inlet portion and an outlet portion, an air channel is formed between the inlet and outlet portions, and the fan is positioned in the air channel; the inner member has an air-guiding portion facing the outer member and disposed between the inlet and outlet portions; the outer member has a first coupling portion, the inner member has a second coupling portion, and the first and second coupling portions jointly couple with the handheld electronic device; the first coupling portion comprises a positioning wall; and the second coupling portion comprises an engaging groove.

In further another implementation, a jacket for a handheld electronic device includes: a housing adapted to couple with a handheld electronic device; a fan mounted in the housing; a temperature sensor adapted to detect the temperature of the handheld electronic device; and a control unit electrically connecting with the fan and the temperature sensor and controlling the fan according to a sensor signal outputted by the temperature sensor, with the handheld electronic device supplying the fan and control unit with electrical power.

In this implementation, one or more of the following features may be included that: the temperature sensor is a thermistor or a surface-attached thermometer; the control unit actuates the fan if the sensor signal is larger than a first threshold value, or the control unit does not actuate the fan; the control unit actuates the fan to rotate at an increased speed if the sensor signal is larger than a second threshold value, or maintains a rotational speed of the fan; the second threshold value is larger than the first threshold value; the control unit gradually increases a rotational speed of the fan to a target speed after the fan is actuated; the control unit is arranged inside the housing; the control unit is arranged inside the fan; according to the sensor signal, the control unit generates a control signal to control the fan; the control signal is a PWM signal, a PAM signal, or a PFM signal; the housing has an electrical connector electrically connecting with the control unit and adapted to connect with the handheld electronic device electrically; the housing has an air purifier electrically connecting with the control unit.

The aforementioned jacket allows the handheld electronic device to dissipate the heat rapidly and prevents overheating of the handheld electronic device. This avoids disadvantages resulting from the overheating of the handheld electronic device such as malfunction, damage or reduction in performance or service life. Thus, the jacket according to the invention does overcome the disadvantages of the conventional ones and meets the actual requirements of the user.

### BRIEF DESCRIPTION OF THE DRAWINGS

The present invention will become more fully understood from the detailed description given hereinafter and the accompanying drawings which are given by way of illustration only, and thus are not limitative of the present invention, including:

FIG. 1 is an exploded and perspective view of a jacket for a handheld electronic device in accordance with an embodiment of the present disclosure.

FIG. 2 is a combined and perspective view of the jacket for the handheld electronic device in accordance with the embodiment.

FIG. 3 is a cross-sectional view of the jacket for the handheld electronic device in use.

FIG. 4 is a cross-sectional view of a handheld assembly in accordance with another embodiment of the present disclosure.

In the various figures of the drawings, the same numerals designate the same or similar parts. Furthermore, when the term “first,” “second,” “inner,” “outer,” “beneath,” “inside,” and similar terms are used hereinafter, it should be understood that these terms refer only to the structure shown in the drawings as it would appear to a person viewing the drawings, and are utilized only to facilitate describing the invention.

### DETAILED DESCRIPTION OF THE INVENTION

For the following contents, terms of “handheld electronic device,” “high power-consumption state,” “communication state,” “online state,” and “high computing load state” are now illustrated. The handheld electronic device is a portable electronic device capable of computation, communication and/or other functions, such as handheld computer, handheld game console, mobile phone, e-book reader, smart phone, tablet, or phablet. The high power-consumption state is a state of the handhold electronic device, wherein the computing load and power consumption are increased rapidly due to the execution of a complex program or of too many parallel programs, or a long-time communication, and thus the handhold electronic device is at high temperature. The communication state is a state of the handhold electronic device, wherein this handhold. electronic device is communicating with another handhold electronic device via telephone network. The online state is a state of the handhold electronic device, wherein the handhold electronic device is linking to the Internet by wireless communication, such as 3G system, 4G system or Wi-Fi. The high computing load state is a state of the handhold electronic device, wherein the computing load is too high, such as larger than 70% of full load, due to the execution of a specific application program, game program or instant audio/video-chatting program for example, or of too many parallel programs simultaneously. The high load can cause the handheld electronic device to enter the high power-consumption state and thus generate heat.

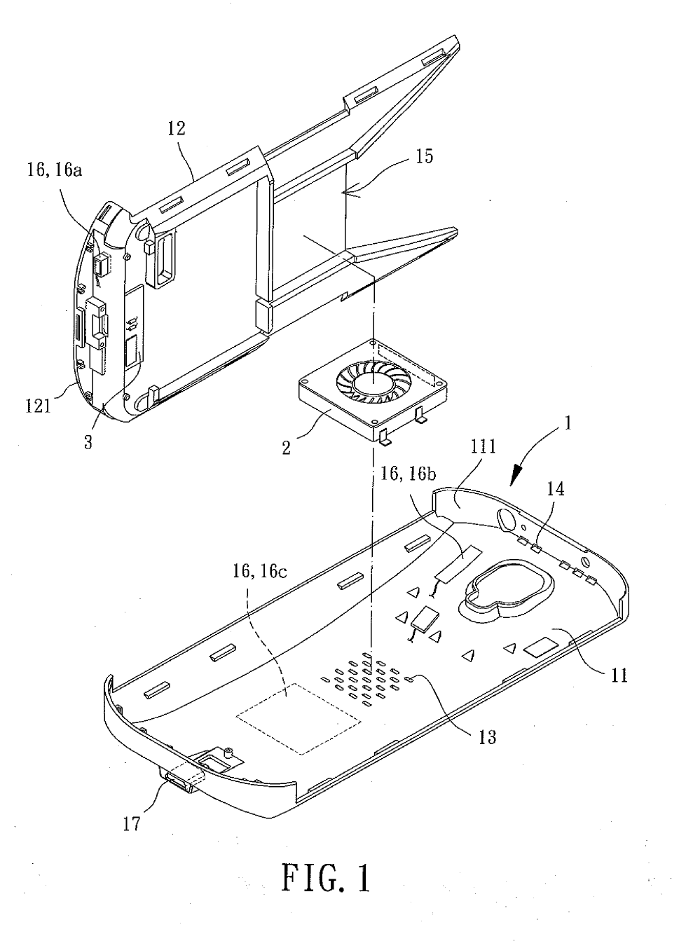

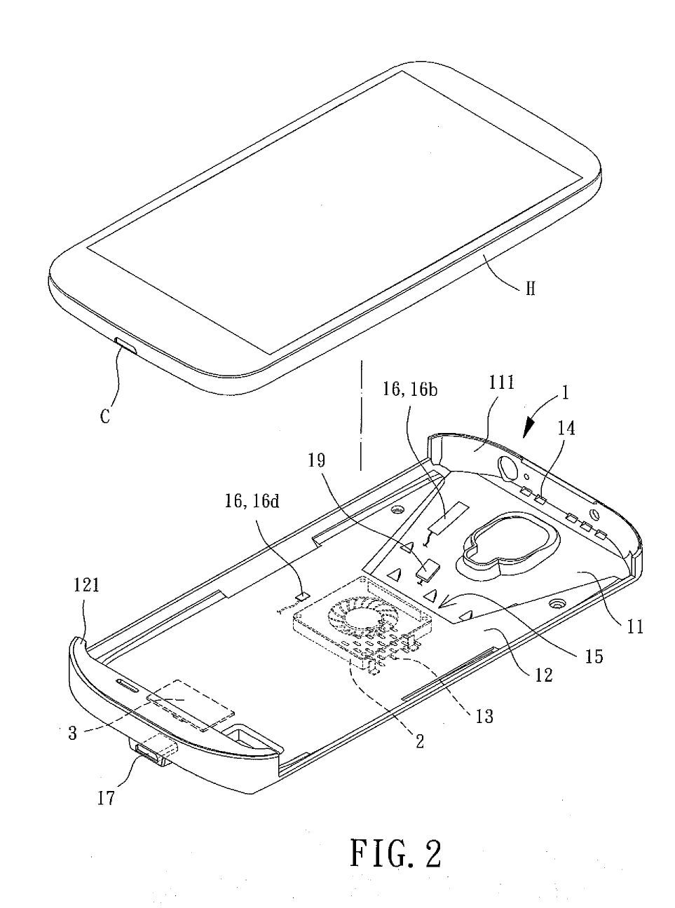

Referring to FIGS. 1 and 2, a jacket for a handheld electronic device of an embodiment of the present disclosure is shown, wherein the jacket includes a housing 1, a fan 2, and a control unit 3. The housing 1 is adapted to connect with a handheld electronic device “H,” the fan 2 is mounted in the housing 1, and the control unit 3 connects with the fan 2 and the handheld electronic device “H” electrically. In this embodiment, the handheld electronic device “H” is a smart phone, but not thus limited.

The housing 1 includes an outer member 11 and an inner member 12 coupling with the outer member 11. The outer member 11 has an inlet portion 13 and an outlet portion 14, with an air channel formed between the inlet and outlet portions 13, 14, and the fan 2, an axial fan or a blower for example, is positioned in the air channel. The inner member 12 has an air-guiding portion 15 facing the outer member 11 and disposed between the inlet and outlet portions 13, 14 for guiding airflow. The outer member 11 further has a first coupling portion 111 while the inner member 12 has a second coupling portion 121 opposite to the first coupling portion 111, so that the first and second coupling portions 111, 121 can jointly couple with the handheld electronic device “H.” For example, the first coupling portion 111 may be a positioning wall, and the second coupling portion 121 may be an engaging groove, so as to respectively engage and position two ends of the handheld electronic device “H.”

In this embodiment, the housing 1 may further has at least one sensor 16 electrically connecting with the control unit 3, so that the control unit 3 may control the fan 2 to be enable/disable or in a power supply state according to the sensor signal generated by the at least one sensor 16. The at least one sensor 16 may include a distance sensor 16a such as an optical sensor or a limit switch. The distance sensor 16a may be arranged inside the inner member 12, mounted in the second coupling portion 121 preferably, so as to detect whether the housing 1 connects with the handheld electronic device “H” or not. However, the at least one sensor 16 may also include a deformation sensor 16b, a electromagnetism sensor 16c and/or a temperature sensor 16d, so as to detect the state of the handheld electronic device “H.” The deformation sensor 16b may be implemented by a piezoelectric sensor or a strain gage; the electromagnetism sensor 16c may be implemented by a proximity switch or a touch element; and the temperature sensor 16d may be implemented by a NTC or PTC thermistor or a surface-attached thermometer. The deformation sensor 16b is preferably arranged at an inner side of the outer member 11, so as to sense the deformation of the outer member 11 due to the hold of a user. The electromagnetism sensor 16c is preferably arranged at an outer side of the outer member 11, so as to sense the touch of the user to the outer member 11, which means that the user is using the handheld electronic device “H.” The temperature sensor 16d is preferably arranged at the inner member 12, so as to sense the temperature of the handheld electronic device “H.”

In this embodiment, the housing 1 may further include an electrical connector 17, such as a Micro USB connector, electrically connecting with the control unit 3. Accordingly, the control unit 3 can electrically connect to a connecting port “C” of the handheld electronic device “H.” via a USB OTG structure, for the handheld electronic device “H” to control the fan 2 and control unit 3. Preferably, the handheld electronic device “H” may provide electrical power to the fan 2 and control unit 3, and the electrical connector 17 may be arranged at the second coupling portion 121 of the inner member 12. The housing 1 may further have a battery such as a Li-battery connecting with the fan 2 and control unit 3 electrically to electrically support them. Moreover, the housing 1 may also have an air purifier 19, such as an air negative ion generator or electrical air freshener, electrically connecting to the control unit 3. Preferably, the air purifier 19 is arranged in the air channel for improving the air propelled by the fan 2.

The control unit 3 may be an electrical member capable of fan control, such as a microcontroller (MCU), preferably an application-specific integrated circuit or a circuit board, serving as a fan controller and driver. The control unit 3 may be arranged on the housing 1 or the fan 2 and has a control program for controlling the operation of the fan 2 according to a control command generated by the handheld electronic device “H.” In this embodiment, the control unit 3 is a circuit board mounted in the housing 1. The control command can be generated by the basic input/output system (BIOS) or an App of the handheld electronic device “H.” The control command may be a digit value presented in bits regarding fan speed control or state of the handheld electronic device “H.”

For example, for fan speed control, “0×00H” represents “stop,” “0×01H” represents “low speed,” “0×02H” represents “high speed,” and “0×03H” represents “full speed;” for state of the handheld electronic device “H,” “0×10H” represents “low power-consumption state,” “0×11H” represents “communication state,” “0×12H” represents “online state,” and “0×13H” represents “high computing load state.”

In operation, by the control command, the control unit 3 can determine whether the handheld electronic device is in a high power-consumption state, such as the communication state, online state, or high computing load state. If the handheld electronic device “H” is in the high power-consumption state, the control unit 3 generates a control signal accordingly, which can be a PWM signal, a PAM signal or a PFM signal, so as to further obtain a driving signal for operating the fan 2, with the driving signal formed by a fan driver receiving the control signal, and the driving signal can be a high level signal or a low level signal. Alternatively, according to the control signal, the control unit 3 may generate the driving signal and actuate the fan 2 directly. Preferably, the rotational speed of the fan 2 increases gradually to a target speed by ways such as gradually increase the duty ratio of the PWM. signal in a duty cycle, so that the starting noise of the fan 2 can be largely decreased. Preferably, the operation time, mode and speed of the fan 2 can be set by the control unit 3 or the control command of the handheld electronic device “H.” When the surface of the handheld electronic device “H” is heated over a predetermined temperature, the control unit 3 may speed up the rotation of the fan 2, or the control unit 3 may maintain its rotational speed if the temperature of the handheld electronic device “H” is not higher than the predetermined temperature. For example, when the control unit 3 determines that the outputted sensor signal of the temperature sensor 16d is larger than a threshold value, which may correspond to 48 degree Celsius, the control unit 3 speeds up the rotation of the fan 2. On the other hand, if the handheld electronic device “H” is not in the high power-consumption state, the control unit 3 may keep detecting whether the handheld electronic device “H” enters the high power-consumption state according to the control command.

In this embodiment, the electrical power supplying situation of the control unit 3 and fan 2 can further be controlled by the distance sensor 16a. For example, if the distance sensor 16a determines that the housing 1 couples with the handheld electronic device “H,” the electrical power may be supplied to the control unit 3 and fan 2; otherwise, the supplied electrical power may be turned off. Furthermore, the control unit 3 can also enable or disable the fan 2 according to the outputted sensor signal of the deformation sensor 16b, electromagnetism sensor 16c or temperature sensor 16d, such as to rotate or stop the fan 2.

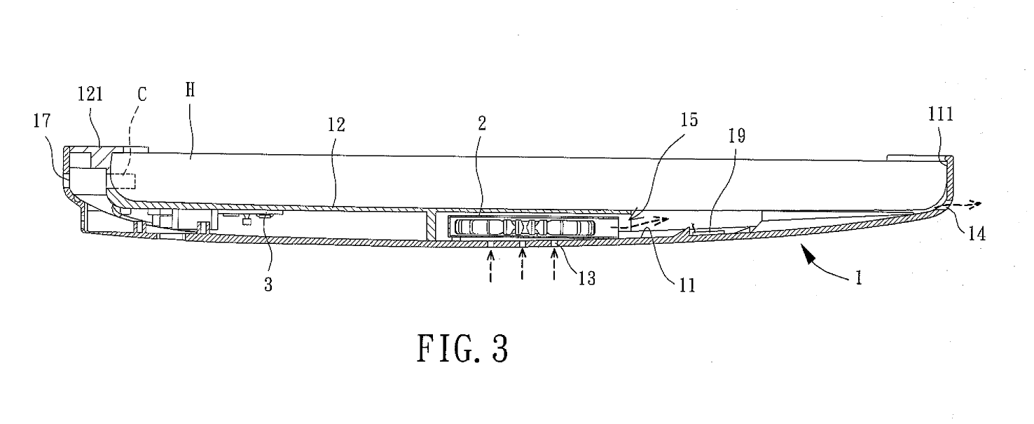

Referring to FIG. 3, the situation of the jacket in use is shown. The housing 1 is coupled with the handheld electronic device “H” for the fan 2 to be located beneath the handheld electronic device “H,” and it is preferable that the handheld electronic device “H” provides electrical power to the fan 2 and control unit 3. For example, the control unit 3 can determine to start the fan 2 or not according to whether the handheld electronic device “H” is in the high power-consumption state or not. If the handheld electronic device “H” is a smart phone, with the control command generated by the smart phone, the control unit 3 may determine whether the smart phone is going to enter the communication state or not. The control unit 3 may output the driving signal to the fan 2 after the smart phone enters the communication state, so as to rotate the fan 2. Accordingly, the fan 2 may guide the external air to the backside of the handheld electronic device “H” to cool the handheld electronic device “H,” and thus prevent the handheld electronic device “H” from overheating. Therefore, operational fault, low efficiency, short lifetime or permanent damage to the handheld electronic device “H” caused by overheating can be thus avoided. During operation of the fan 2, the control unit 3 can further enable the purifier 19 to improve the air around the handheld electronic device “H.”

Moreover, referring to FIGS. 1 and 2 again, in the following another embodiment, the fan 2 can alternatively be operated according to the sensor signal outputted by the temperature sensor 16d. In this embodiment, the jacket for a handheld electronic device includes the housing 1, the fan 2, the temperature sensor 16d, and the control unit 3. The housing 1 is adapted to couple with the handheld electronic device “H” the fan 2 is mounted in the housing 1, the temperature sensor 16d is adapted to detect the temperature of the handheld electronic device “H,” and the control unit 3 electrically connects with the fan 2 and temperature sensor 16d. The control unit 3 controls the operation of the fan 2 according to the sensor signal outputted by the temperature sensor 16d. For example, the control unit 3 generates the control signal such as a PWM signal, a PAM signal or a PFM signal according to the sensor signal, so as to control the fan 2, and the electrical power supplied to the control unit 3 and the fan 2 is provided by the handheld electronic device “H.” If the sensor signal is larger than a first threshold value such as 30 degrees Celsius, the control unit 3 may output the control signal to actuate the fan 2; otherwise, the control unit 3 does not actuate the fan 2, that is, keeps the rotational speed of the fan 2 at zero. If the sensor signal is larger than a second threshold value, which is larger than the first threshold value, such as 48 degrees Celsius, the control unit 3 actuates the fan 2 to rotate at an increased speed; otherwise, the control unit 3 maintains the rotational speed of the fan 2. Preferably, the control unit 3 may increase the rotational speed of the fan 2 gradually to a target speed. The control unit 3 may be arranged inside the housing 1 or the fan 2. The housing 1 may further include an electrical connector 17 electrically connecting with the control unit 3 and the handheld electronic device “H,” so that the handheld electronic device “H” may provide electrical power to the control unit 3 and the fan 2.

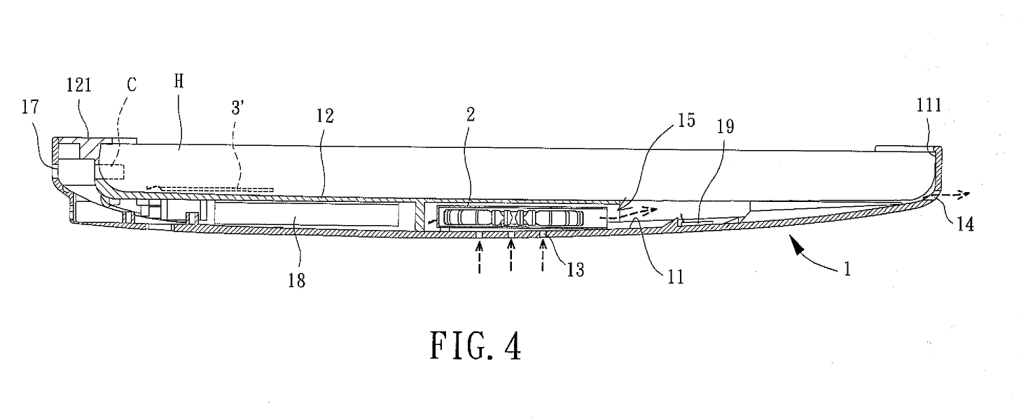

In a further embodiment shown in FIG. 4, a handheld assembly including a jacket and the handheld electronic device “H” is provided. This handheld assembly includes the housing 1, the handheld electronic device “H,” and the fan 2. The handheld electronic device “H” couples with the housing 1 and generates the control signal. The fan 2 is mounted in the housing 1 and electrically connects with the handheld electronic device “H,” so the fan 2 operates accordingly to the control signal. It should be noted that, in this embodiment, instead of the control unit 3 arranged in the jacket, a control unit 3′ is arranged inside the handheld electronic device “H” and generates the control signal. The control unit 3′ as shown in FIG. 4 may be implemented by a processor of the handheld electronic device “H” such as the one shown in FIG. 4, or a hardware or application program with the same function. When the housing 1 couples with the fan 2, the handheld electronic device “H” may supply electrical power to and control the fan 2. A hardware or application program of the handheld electronic device “H” may generate the control command, and the control unit 3′ generates the control signal, such as a PWM, PAM, or PFM signal, according to the control command for a fan driver to drive the fan 2. Therefore, the fan 2 may adjust its operation state such as rotation or not, rotational speed, or time of operation according to the control signal of the handheld electronic device “H.” The operation state can also be shown by a GUI of the handheld electronic device “H,” and the GUI may also include an icon for a user to click and thus control the enablement of the fan 2.

In this embodiment, there may also be an electrical connector 17 and an air purifier 19. The electrical connector 17 connects with the fan 2 and the handheld electronic device “H” electrically for the handheld electronic device “H” to control the fan 2 and to supply the fan 2 with electrical power. However, the necessary power of the fan 2 can also be provided by a battery 18. The air purifier 19 is arranged in the air channel between the inlet portion 13 and the outlet portion 14, preferably adjacent to an inlet or outlet of the fan 2, so as to improve the air quality.

In sum, the jacket for a handheld electronic device of the present disclosure is mainly characterized in the following features. The jacket includes the housing 1, the fan 2 and the control unit 3 or 3′. The housing 1 is adapted to connect with the handheld electronic device “H,” the fan 2 is mounted in the housing 1, the control unit 3 may be arranged on the housing 1 or the fan 2, and the control unit 3′ is arranged inside the handheld electronic device “H.” The control unit 3 or 3′ is adapted to control the fan 2, so that the fan 2 operates according to the control command or control signal generated by the handheld electronic device “H” or the sensor signal outputted by the temperature sensor 16d. Therefore, according to states of the handheld electronic device “H” such as its temperature or operation, the control unit 3 or 3′ may determine whether it is necessary to actuate the fan 2, so as to cool the handheld electronic device “H.” In comparison with the conventional jacket without any design for cooling, the jacket of the present disclosure may prevent the handheld electronic device “H” from overheating that may cause operational fault, low efficiency, short lifetime or permanent damage to the handheld electronic device “H.”

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A jacket for a handheld electronic device, comprising:
a housing adapted to couple with a handheld electronic device;
a fan mounted in the housing; and
a control unit electrically connecting with the fan and adapted to electrically connect with the handheld electronic device, with the control unit capable of controlling the fan according to a control command outputted by the handheld electronic device.

2. The jacket for the handheld electronic device as claimed in claim 1, wherein the control unit is arranged inside the housing.

3. The jacket for the handheld electronic device as claimed in claim 1, wherein the control unit is arranged inside the fan.

4. The jacket for the handheld electronic device as claimed in claim 1, wherein, according to the control command, the control unit generates a driving signal to actuate the fan.

5. The jacket for the handheld electronic device as claimed in claim 1, wherein, according to the control command, the control unit generates a control signal for a fan driver to actuate the fan.

6. The jacket for the handheld electronic device as claimed in claim 5, wherein the control signal is a PWM signal, a PAM signal, or a PFM signal.

7. The jacket for the handheld electronic device as claimed in claim 1, wherein the control unit is a microcontroller.

8. The jacket for the handheld electronic device as claimed in claim 1, wherein the control unit is an application-specific integrated circuit able to serve as a fan controller and driver.

9. The jacket for the handheld electronic device as claimed in claim 1, wherein the control unit is a circuit board having a fan controller and a fan driver.

10. The jacket for the handheld electronic device as claimed in claim 1, wherein the housing has at least one sensor electrically connecting with the control unit.

11. The jacket for the handheld electronic device as claimed in claim 10, wherein the at least one sensor comprises at least one of a distance sensor, a deformation sensor, an electromagnetism sensor and a temperature sensor.

12. The jacket for the handheld electronic device as claimed in claim 11, wherein the distance sensor is an optical sensor or a limit switch.

13. The jacket for the handheld electronic device as claimed in claim 11, wherein the deformation sensor is a piezoelectric sensor or a strain gage.

14. The jacket for the handheld electronic device as claimed in claim 11, wherein the electromagnetism sensor is a proximity switch or a touch element.

15. The jacket for the handheld electronic device as claimed in claim 11, wherein the temperature sensor is a thermistor or a surface-attached thermometer.

16. The jacket for the handheld electronic device as claimed in claim 1, wherein the housing has a battery electrically connecting with the control unit and the fan.

17. The jacket for the handheld electronic device as claimed in claim 16, wherein the battery supplies electrical power to the control unit and the fan.

18. The jacket for the handheld electronic device as claimed in claim 1, wherein the housing has an air purifier electrically connecting to the control unit.

19. The jacket for the handheld electronic device as claimed in claim 18, wherein the air purifier is an air negative ion generator or an electrical air freshener.

20. The jacket for the handheld electronic device as claimed in claim 1, wherein the housing has an electrical connector electrically connecting with the control unit and adapted to connect with the handheld electronic device electrically.

21. The jacket for the handheld electronic device as claimed in claim 20, wherein the handheld electronic device provides electrical power to the control unit and the fan.

22. The jacket for the handheld electronic device as claimed in claim 1, wherein the control command is generated by an application program executed by the handheld electronic device.

23. The jacket for the handheld electronic device as claimed in claim 1, wherein the control command is generated by a basic input/output system of the handheld electronic device.

24. The jacket for the handheld electronic device as claimed in claim 1, wherein the control unit determines whether the handheld electronic device is in a high power-consumption state according to the control command, wherein the control unit actuates the fan to turn if the handheld electronic device is in the high power-consumption state, or keeps detecting whether the handheld electronic device enters the high power-consumption state according to the control command if the handheld electronic device is not in the high power-consumption state.

25. The jacket for the handheld electronic device as claimed in claim 24, wherein the high power-consumption state is a communication state, an online state, or a high computing load state.

26. The jacket for the handheld electronic device as claimed in claim 24, wherein, when the control unit actuates the fan, the control unit speeds up rotation of the fan if a surface of the handheld electronic device is heated over a predetermined temperature, or the control unit maintains a rotational speed of the fan if the surface of the handheld electronic device is not heated over the predetermined temperature.

27. The jacket for the handheld electronic device as claimed in claim 24, wherein the control unit gradually increases a rotational speed of the fan to a target speed after the fan is actuated.

28. The jacket for the handheld electronic device as claimed in claim 1, wherein the housing has an outer member and an inner member coupling with the outer member.

29. The jacket for the handheld electronic device as claimed in claim 28, wherein the outer member has an inlet portion and an outlet portion, an air channel is formed between the inlet and outlet portions, and the fan is located in the air channel.

30. The jacket for the handheld electronic device as claimed in claim 29, wherein the inner member has an air-guiding portion facing the outer member and disposed between the inlet and outlet portions.

31. The jacket for the handheld electronic device as claimed in claim 28, wherein the outer member has a first coupling portion, the inner member has a second coupling portion, and the first and second coupling portions jointly couple with the handheld electronic device.

32. The jacket for the handheld electronic device as claimed in claim 31, wherein the first coupling portion comprises a positioning wall.

33. The jacket for the handheld electronic device as claimed in claim 31, wherein the second coupling portion comprises an engaging groove.

34. A handheld assembly comprising:
a housing;
a handheld electronic device coupling with the housing and generating a control signal; and
a fan mounted in the housing, electrically connecting with the handheld electronic device, and operating accordingly to the control signal.

35. The handheld assembly as claimed in claim 34, wherein the handheld electronic device has a control unit that generates the control signal.

36. The handheld assembly as claimed in claim 34, wherein the control signal is adapted to be supplied to a fan driver to actuate the fan.

37. The handheld assembly as claimed in claim 34, wherein the control signal is a PWM signal, a PAM signal, or a PFM signal.

38. The handheld assembly as claimed in claim 34, wherein the housing has an electrical connector electrically connecting with the fan and the handheld electronic device.

39. The handheld assembly as claimed in claim 38, wherein the handheld electronic device provides electrical power to the fan.

40. The handheld assembly as claimed in claim 34, wherein the housing has a battery connecting with the fan electrically.

41. The handheld assembly as claimed in claim 40, wherein the battery supplies electrical power to the fan.

42. The handheld assembly as claimed in claim 34, wherein the housing has an air purifier adjacent to the fan.

43. The handheld assembly as claimed in claim 42, wherein the air purifier is an air negative ion generator or an electrical air freshener.

44. The handheld assembly as claimed in claim 34, wherein the control signal is generated by an application program executed by the handheld electronic device.

45. The handheld assembly as claimed in claim 34, wherein the control signal is generated by a basic input/output system of the handheld electronic device.

46. The handheld assembly as claimed in claim 35, wherein, according to a control command, the control unit determines whether the handheld electronic device is in a high power-consumption state, wherein the control unit actuates the fan to turn if the handheld electronic device is in the high power-consumption state, or keeps detecting whether the handheld electronic device enters the high power-consumption state according to the control command if the handheld electronic device is not in the high power-consumption state.

47. The handheld assembly as claimed in claim 46, wherein the high power-consumption state is a communication state, an online state, or a high computing load state.

48. The handheld assembly as claimed in claim 46, wherein the control unit gradually increases a rotational speed of the fan to a target speed after the fan is actuated.

49. The handheld assembly as claimed in claim 34, wherein the housing has an outer member and an inner member coupling with the outer member.

50. The handheld assembly as claimed in claim 49, wherein the outer member has an inlet portion and an outlet portion, an air channel is formed between the inlet and outlet portions, and the fan is located in the air channel.

51. The handheld assembly as claimed in claim 49, wherein the inner member has an air-guiding portion facing the outer member and disposed between the inlet and outlet portions.

52. The handheld assembly as claimed in claim 49, wherein the outer member has a first coupling portion, the inner member has a second coupling portion, and the first and second coupling portions jointly couple with the handheld electronic device.

53. The handheld assembly as claimed in claim 52, wherein the first coupling portion comprises a positioning wall.

54. The handheld assembly as claimed in claim 52, wherein the second coupling portion comprises an engaging groove.

55. A jacket for a handheld electronic device, comprising:
a housing adapted to couple with a handheld electronic device;
a fan mounted in the housing;
a temperature sensor adapted to detect the temperature of the handheld electronic device; and
a control unit electrically connecting with the fan and the temperature sensor and controlling the fan according to a sensor signal outputted by the temperature sensor, with the handheld electronic device adapted to supply the fan and the control unit with electrical power.

56. The jacket for the handheld electronic device as claimed in claim 55, wherein the temperature sensor is a thermistor or a surface-attached thermometer.

57. The jacket for the handheld electronic device as claimed in claim 55, wherein the control unit actuates the fan if the sensor signal is larger than a first threshold value, or the control unit does not actuate the fan.

58. The jacket for the handheld electronic device as claimed in claim 57, wherein the control unit actuates the fan to rotate at an increased speed if the sensor signal is larger than a second threshold value, or maintains a rotational speed of the fan.

59. The jacket for the handheld electronic device as claimed in claim 58, wherein the second threshold value is larger than the first threshold value.

60. The jacket for the handheld electronic device as claimed in claim 57, wherein the control unit gradually increases a rotational speed of the fan to a target speed after the fan is actuated.

61. The jacket for the handheld electronic device as claimed in claim 55, wherein the control unit is arranged inside the housing.

62. The jacket for the handheld electronic device as claimed in claim 55, wherein the control unit is arranged inside the fan.

63. The jacket for the handheld electronic device as claimed in claim 55, wherein, according to the sensor signal, the control unit generates a control signal to control the fan.

64. The jacket for the handheld electronic device as claimed in claim 63, wherein the control signal is a PWM signal, a PAM signal, or a PFM signal.

65. The jacket for the handheld electronic device as claimed in claim 55, wherein the housing has an electrical connector electrically connecting with the control unit and adapted to connect with the handheld electronic device electrically.
